(19) United States
(12) Patent Application Publication
(10) Pub. No.: US 2022/0332978 A1
(43) Pub. Date: Oct. 20, 2022

(54) Low Dishing Copper Chemical Mechanical Planarization

(71) Applicant: Versum Materials US, LLC, Tempe, AZ (US)

(72) Inventors: KEH-YEUAN LI, Hisinchu (TW); MING SHIH TSAI, Hsinchu (TW); XIAOBO SHI, Chandler, AZ (US); RUNG-JE YANG, Hsinchu (TW); CHEN YUAN HUANG, Hsinchu (TW); LAURA M. MATZ, Chandler, AZ (US)

(73) Assignee: Versum Materials US, LLC, Tempe, AZ (US)

(21) Appl. No.: 17/753,998

(22) PCT Filed: Sep. 28, 2020
(86) PCT No.: PCT/US2020/053000

§ 371 Date: Mar. 21, 2022

Related U.S. Application Data
(60) Provisional application No. 62/907,912, filed on Sep. 30, 2019.

(51) Int. Cl. C09G 1/02; H01L 21/321

(52) U.S. Cl. CPC C09G 1/02; H01L 21/3212

(57) ABSTRACT

Copper chemical mechanical planarization (CMP) polishing formulation, method and system are disclosed. The CMP polishing formulation comprises abrasive particles of specific morphology and mean particle sizes (≤100 nm, ≤50 nm, ≤40 nm, ≤30 nm, or ≤20 nm), at least two or more amino acids, oxidizer, corrosion inhibitor, and water.

### CROSS-REFERENCE TO RELATED APPLICATIONS

This application claims priority to U.S. provisional application 62/907,912 filed on Sep. 30, 2019, the entire contents of which is incorporated herein by reference thereto for all allowable purposes.

### BACKGROUND OF THE INVENTION

This invention relates generally to the chemical-mechanical planarization (CMP) of semiconductor wafers. More specifically, present invention relates to low dishing formulations used for CMP copper (Cu)-containing substrates. CMP polishing formulations, CMP polishing compositions or CMP polishing slurries are interchangeable in present invention.

Copper is the current material of choice for interconnect metal used in the fabrication of integrated electronic devices due to its low resistivity, high reliability, and scalability. Copper chemical mechanical planarization processes are necessary to remove copper overburden from inlaid trench structures while achieving global planarization with low metal loss.

With advancing technology nodes the need to reduce metal dishing and metal loss becomes increasingly important. Any new polishing formulations must also maintain high removal rates, high selectivity to the barrier material and low defectivity.

CMP polishing formulations for copper CMP have been disclosed in the prior arts, for example, in. US20040175942, U.S. Pat. Nos. 6,773,476, 8,236,695 and 9,978,609 B2.

This invention discloses bulk copper CMP polishing formulations developed to meet challenging requirements of low dishing and high removal rates for the advanced technology nodes.

### BRIEF SUMMARY OF THE INVENTION

In one aspect, the present invention provides a copper chemical mechanical planarization (CMP) polishing formulation comprising:
abrasive particles,
at least two amino acids,
oxidizer,
corrosion inhibitor,
and
liquid carrier.

In another aspect, the present invention provides a method of chemical mechanical planarization polishing a copper containing semiconductor substrate, comprising steps of:
providing the semiconductor substrate having a surface containing copper;
providing a polishing pad;
providing a chemical mechanical planarization (CMP) polishing formulation comprising
   abrasive particles,
   at least two amino acids,
   oxidizer,
   corrosion inhibitor,
   and
   liquid carrier;
contacting the surface of the semiconductor substrate with the polishing pad and the chemical mechanical planarization (CMP) polishing formulation; and
polishing the surface of the semiconductor;
wherein at least a portion of the surface containing copper is in contact with both the polishing pad and the chemical mechanical planarization (CMP) polishing formulation.

In yet another aspect, the invention provides a system of chemical mechanical planarization polishing, comprising
a semiconductor substrate having a surface containing copper;
providing a polishing pad;
providing a chemical mechanical planarization (CMP) polishing formulation comprising
   abrasive particles,
   at least two amino acids,
   oxidizer,
   corrosion inhibitor,
   and
   liquid carrier;
wherein at least a portion of the surface containing copper is in contact with both the polishing pad and the chemical mechanical planarization (CMP) polishing formulation.

The abrasive particles include, but are not limited to fumed silica, colloidal silica, high purity colloidal silica, fumed alumina, colloidal alumina, cerium oxide, titanium dioxide, zirconium oxide, surface modified or lattice doped inorganic oxide particles, polystyrene, polymethyl methacrylate, mica, hydrated aluminum silicate, and mixtures thereof. The abrasive particles concentration may range from 0.0001 to 2.5 wt. %, 0.0005 to 1.0 wt. %, 0.001 to 0.5 wt. %, 0.005 to 0.5 wt. %, or, 0.01 to 0.25 wt. %.

The abrasive particles have mean particle sizes ranging from about 2 nm to 160 nm, 2 nm to 100 nm, 2 nm to 80 nm, 2 to 60 nm, 3 to 50 nm, 3 to 40, 4 nm to 30 nm, or 5 to 20 nm.

Or, the abrasive particles have mean particle sizes ≤100 nm, ≤50 nm, ≤40 nm, ≤30 nm, or ≤20nm.

A variety of amino acids including derivatives are organic compounds containing amine and carboxylic acid functional groups. Additional functional groups may also be present in the amino acid structures. The amino acids can be used in the composition including but are not limited to aminoacetic acid (also known as glycine), serine, lysine, glutamine, L-alanine, DL-alanine, Beta-alanine, iminoacetic acid, asparagine, aspartic acid, valine, sarcosine, bicine, tricin, proline, and mixtures thereof. A preferred combinations of amino acids include glycine (aminoacetic acid), alanine, bicine, and sarcosine.

The concentration of each amino acid is within the range of about 0.01 wt. % to about 20.0 wt. %; 0.1 wt. % to about 15.0 wt. %, or 0.5 wt. to 10.0 wt. %.

The weight concentration ratio of one amino acid to another amino acid used in the slurry ranges from 1:99 to 99:1; from 10:90 to 90:10, 20:80 to 80:20, 25:75 to 75:25. 30:70 to 70:30, 40:60 to 60:40, or 50:50.

The corrosion inhibitors include but are not limited to nitrogenous cyclic compounds such as 1, 2, 3-triazole, 1, 2, 4-triazole, 3-amino-1,2,4-triazole, 1, 2, 3-benzotriazole, 5-methylbenzotriazole, benzotriazole, 1-hydroxybenzotriazole, 4-hydroxybenzotriazole, 4-amino-4H-1, 2, 4-triazole, and benzimidazole. Benzothiazoles such as 2, 1, 3-benzothiadiazole, triazinethiol, triazinedithiol, and triazinetrithiol can also be used. Preferred inhibitors are 1,2,4-triazole, 5 amino triazole, 3-amino-1,2,4-triazole and isocyanurate compounds such as 1,3,5-tris(2-hydroxyethyl)isocyanurate.

The corrosion inhibitor is incorporated at a concentration level in the range of about 0.1 ppm to about 20,000 ppm by weight, preferably about 20 ppm to about 10,000 ppm by weight, and more preferably about 50 ppm to about 1000 ppm by weight.

The oxidizing agent includes but is not limited to hydrogen peroxide, ammonium dichromate, ammonium perchlorate, ammonium persulfate, benzoyl peroxide, bromates, calcium hypochlorite, ceric sulfate, chlorates, chromium trioxide, ferric trioxide, ferric chloride, iodates, iodine, magnesium perchlorate, magnesium dioxide, nitrates, periodic acid, permanganic acid, potassium dichromate, potassium ferricyanide, potassium permanganate, potassium persulfate, sodium bismuthate, sodium chlorite, sodium dichromate, sodium nitrite, sodium perborate, sulfates, peracetic acid, urea-hydrogen peroxide, perchloric acid, di-t-butyl peroxide, monopersulfates and dipersulfates, and combinations thereof.

The oxidizing agent has a concentration in the range of about 0.1% to about 20% by weight, preferably about 0.25% to about 5% by weight.

The CMP polishing formulation further comprises planarization efficiency enhancer. The planarization efficiency enhancer is used for enhancing the planarization, such as improving dishing among various copper lines and/or features. It includes but is not limited to choline salt; such as 2-Hydroxyethyl)trimethylammonium bicarbonate, choline hydroxide, choline p-toluene-sulfonate, choline bitartrate, and all other salts formed between choline and other anionic counter ions; organic amine, such as ethylene diamine, propylene diamine, organic amine compounds containing multi amino groups in the same molecular framework; and combinations thereof.

The planarization efficiency enhancer has a concentration in the range of 5 to 1000ppm, 10 to 500 ppm, or 10 to 100 ppm.

The CMP polishing formulation further comprises surfactants, include, but are not limited to phenyl ethoxylate surfactant, acetylenic diol surfactant, sulfate or sulfonate surfactant, glyceroal propoxylate, glyceroal ethoxylate, polysorbate surfactant, non-ionic alkyl ethoxylate surfactant, glycerol propoxylate-block-ethoxylate, amine oxide surfactant, glycolic acid ethoxylate oleyl ether, polyethylene glycol, polyethylene oxide, ethoxylated alcohols, ethoxylate-propoxylate surfactant, polyether defoaming dispersion, and other surfactants.

Surfactant concentration can be in the range of 0.0001 to 1.0 wt. %, 0.0005 to 0.5 wt. %, or, 0.001 to 0.3 wt. %.

The liquid carrier includes but is not limited to DI water, a polar solvent and a mixture of DI water and polar solvent. The polar solvent can be any alcohol, ether, ketone, or other polar reagent. Examples of polar solvents include alcohols, such as isopropyl alcohol, ethers, such as tetrahydrofuran and diethyl ether, and ketones, such as acetone. Advantageously the water is deionized (DI) water.

The CMP polishing formulation further comprises at least one selected from the group consisting of pH adjusting agent, biocide or biological preservative, dispersing agent, and wetting agent.

The polishing formulation has a pH from 2 to 12, 3 to 10, 4 to 9, or 6 to 8.

### DETAILED DESCRIPTION OF THE INVENTION

Bulk copper CMP polishing formulations developed for the advanced technology node is disclosed in present invention. The formulations have shown improved dishing performance.

Formulations comprise abrasive particles, two or more amino acids, oxidizer, a copper corrosion inhibitor, and liquid carrier.

The weight % or wt. % is to the total weight of the formulation or composition. Parts per million by weight, or ppm by weight, or simply ppm is also used. 1000 ppm by weight or 1000 ppm=0.1 wt. %.

Generally, a wide range of abrasive particles can be used. The particles can be obtained through a variety of manufacturing and processing techniques, including but not limited to thermal processes, solution growth processes, mining of raw ore and grinding to size, and rapid thermal decomposition. The materials can be incorporated into the composition generally as supplied by the manufacturer. Certain types of the abrasive particles used in the composition at higher concentrations as abrasive materials. However, other abrasive particles which have not traditionally been used as abrasives in CMP slurries can also be used to provide advantageous results.

Representative abrasive particles include a variety of inorganic and organic materials which are inert under the use conditions of the slurries of the invention.

The abrasive particles include, but are not limited to fumed silica, colloidal silica, high purity colloidal silica, fumed alumina, colloidal alumina, cerium oxide, titanium dioxide, zirconium oxide, surface modified or lattice doped inorganic oxide particles, polystyrene, polymethyl methacrylate, mica, hydrated aluminum silicate, and mixtures thereof.

The abrasive particles have mean particle sizes ranging from about 2 nm to 160 nm, 2 nm to 100 nm, 2 nm to 80 nm, 2 to 60 nm, 3 to 50 nm, 3 to 40, 4 nm to 30 nm, or 5 to 20 nm.

Or, the abrasive particles have mean particle sizes ≤100 nm, ≤50 nm, ≤40 nm, ≤30 nm, or ≤20nm.

The mean particle sizes are measured by Disk Centrifuge (DC).

The particles may exist in a variety of physical forms, such as but not limited to platelet, fractal aggregate, cocoon and spherical species.

The preferred abrasive particles are colloidal silica. Still preferred is colloidal silica with very low levels of trace metal impurities.

Examples of high purity colloidal silica can be purchased from Fuso Chemical Company, Japan. The high purity colloidal silica particles have mean particle sizes ranging from around 6nm to about 180nm and have spherical, cocoon, or aggregate shapes. The high purity colloidal silica particles can also have the surface modified by functional groups

A mixture of colloidal silica particles of different particle sizes and types may also be used to yield improved performance.

The abrasive particles concentration may range from 0.0001 to 2.5 wt. %, 0.0005 to 1.0 wt. %, 0.001 to 0.5 wt. %, 0.005 to 0.5 wt. %, or 0.01 to 0.25 wt. %.

The formulations comprise at least two amino acids as chelators.

A variety of amino acids and derivatives, referred as amino acids in the present invention, can be used in the preparation of the CMP polishing formulation.

Amino are defined as organic compounds containing amine and carboxylic acid functional groups. Additional functional groups may also be present in the amino acid structures.

The amino acids can be used in the formulation including but are not limited to aminoacetic acid (also known as glycine), serine, lysine, glutamine, L-alanine, DL-alanine, Beta-alanine, iminoacetic acid, asparagine, aspartic acid, valine, sarcosine, bicine, tricin, proline, and mixtures thereof.

A preferred combinations of amino acids include glycine (aminoacetic acid), alanine, bicine, and sarcosine.

The presence of amino acids in the formulation has been found to affect the rate of copper removal during the CMP process. However, increased amino acid levels increase the etching rate of the copper, which is undesirable. Concentration levels are therefore adjusted to achieve an acceptable balance between copper rate of removal and the etching rate.

Typically, the concentration of each amino acid is in the range of about 0.01 wt. % to about 20.0 wt. %; 0.1 wt. % to about 15.0 wt. %, or 0.5 wt. to 10.0 wt. %.

The weight concentration ratio of one amino acid to another amino acid used in the slurry ranges from 1:99 to 99:1; from 10:90 to 90:10, 20:80 to 80:20, 25:75 to 75:25. 30:70 to 70:30, 40:60 to 60:40, or 50:50.

The formulation can comprise a corrosion inhibitor to limit metal corrosion and etching during the CMP process. The corrosion inhibitor forms a protective film on the metal surface by either physical adsorption or chemical adsorption. Thus, the corrosion inhibitor operates to protect the copper surface from the effects of etching and corrosion during the CMP process.

The corrosion inhibitors include but are not limited to nitrogenous cyclic compounds such as 1, 2, 3-triazole, 1, 2, 4 triazole, 3-amino-1,2,4-triazole, 1, 2, 3-benzotriazole, 5-methylbenzotriazole, benzotriazole, 1-hydroxybenzotriazole, 4-hydroxybenzotriazole, 4-amino-4H-1, 2, 4-triazole, 5-amino triazole, and benzimidazole. Benzothiazoles such as 2, 1, 3-benzothiadiazole, triazinethiol, triazinedithiol, and triazinetrithiol can also be used. Preferred inhibitors are 1,2,4-triazole, 3-amino-1,2,4-triazole and 5-amino triazole.

The corrosion inhibitor is incorporated at a concentration level in the range of about 0.1 ppm to about 20,000 ppm by weight, preferably about 20 ppm to about 10,000 ppm by weight, and more preferably about 50 ppm to about 1000 ppm by weight.

The oxidizing agent performs an oxidizing function and facilitates conversion of copper on the wafer surface to hydrated copper compounds of either CuOH, Cu (OH) 2, CuO, or Cu2O.

The oxidizing agent includes but is not limited to hydrogen peroxide, ammonium dichromate, ammonium perchlorate, ammonium persulfate, benzoyl peroxide, bromates, calcium hypochlorite, ceric sulfate, chlorates, chromium trioxide, ferric trioxide, ferric chloride, iodates, iodine, magnesium perchlorate, magnesium dioxide, nitrates, periodic acid, permanganic acid, potassium dichromate, potassium ferricyanide, potassium permanganate, potassium persulfate, sodium bismuthate, sodium chlorite, sodium dichromate, sodium nitrite, sodium perborate, sulfates, peracetic acid, urea-hydrogen peroxide, perchloric acid, di-t-butyl peroxide, monopersulfates and dipersulfates, and combinations thereof.

Preferably the oxidizing agent is incorporated into the formulation on site at the time of use or shortly prior thereto. It is also possible to incorporate the oxidizing agent at the time of combining the other components, though stability of the thus-formed formulation over longer storage conditions must be taken into consideration.

The oxidizing agent has a concentration in the range of about 0.1% to about 20% by weight, preferably about 0.25% to about 5% by weight.

The CMP polishing formulation further comprises planarization efficiency enhancer. The planarization efficiency enhancer is used for enhancing the planarization, such as improving dishing among various copper lines and/or features. It includes but is not limited to choline salt; such as 2-Hydroxyethyl)trimethylammonium bicarbonate, choline hydroxide, choline p-toluene-sulfonate, choline bitartrate, and all other salts formed between choline and other anionic counter ions; organic amine, such as ethylene diamine, propylene diamine, organic amine compounds containing multi amino groups in the same molecular framework; and combinations thereof.

The planarization efficiency enhancer has a concentration in the range of 5 to 1000ppm, 10 to 500 ppm, or 10 to 100 ppm.

Surfactants when added to these formulations are also found to have useful impact in reducing dishing and defects. Surfactants can be non-ionic, cationic, anionic or zwitterionic.

The examples of surfactants include, but are not limited to phenyl ethoxylate type surfactant such as Nonidet™ P40 (octylphenoxypolyethoxyethanol) from Dow Chemicals and acetylenic diol surfactant such as Dynol™ 607, Dynol™ 800, Dynol™ 810, Dynol™ 960, Dynol™ 980, Surfynol™ 104E, Surfynol® 465, Surfynol® 485, Surfynol® PSA 336, Surfynol® FS85, Surfynol® SE, Surfynol® SE-F, from Evonik Industries; anionic organic surfactants such as sulfate or sulfonate surfactants; such as ammonium dodecyl sulfate (ADS), sodium decyl sulfate, tetradecyl sulfate sodium salt or linear alkylbenzene sulfate; glyceroal propoxylates; glyceroal ethoxylates; polysorbate surfactants such as Tween® 20, Tween® 40, Tween® 60, Tween® 80, from BASF; non-ionic alkyl ethoxylate type surfactants such as Brij™ LA-4 from Croda; glycerol propoxylate-block-ethoxylates; amine oxide surfactants such as Tomamine® AO-455 and Tomamamine AO®-405, from Evonik Insustries; glycolic acid ethoxylate oleyl ether surfactants; polyethylene glycols; polyethylene oxide; ethoxylated alcohols such as Tomadol® 23-6.5, Tomadol® 91-8, Carbowet® 13-40, from Evonik Industries; ethoxylate-propoxylate surfactants such as Tergitol™ Minfoam 1×, Tergitol™ Minfoam 2×, from Dow Chemical; polyether defoaming dispersant such as DF204 from PPG Industries, and other surfactants.

The preferred surfactants for effectively reducing Cu line dishing are include phenyl ethoxylate (e.g. Nonidet™ P40), acetylenic diol surfactant (e.g. Surfynol®104E, Dynol® 607, Dyno® 800, Dynol® 810), ethoxylate-propoxylate surfactants such as Tergitol Minfoam 1×, polyether dispersions (e.g. DF204); anionic organic sulfate/sulfonate surfactants such as ammonium dodecyl sulfate (ADS), sodium decyl sulfate, tetradecyl sulfate sodium salt or linear alkylbenzene sulfate.

Surfactant concentration can be in the range of 0.0001 to 1.0 wt. %, 0.0005 to 0.5 wt. %, or, 0.001 to 0.3 wt. %.

The formulations may also comprise other optional additives such as biocides or biological preservative, dispersing agents, wetting agents, pH adjusting agent etc.

The CMP polishing formulation may comprise biocides, i.e., biological growth inhibitors or preservatives to prevent bacterial and fungal growth during storage. The biological growth inhibitors include, but are not limited to, tetramethylammonium chloride, tetraethylammonium chloride, tetrapropylammonium chloride, alkylbenzyldimethylammonium chloride, and alkylbenzyldimethylammonium hydroxide, wherein the alkyl chain ranges from 1 to about 20 carbon atoms, sodium chlorite, and sodium hypochlorite. Some of the commercially available preservatives include KATHON™ (such as Kathon II) and NEOLENE™ product families from Dow Chemicals, and Preventol™ family from Lanxess. More are disclosed in U.S. Pat. No. 5,230,833 (Romberger et al.) and US Patent Application No. US 20020025762. The contents of which are hereby incorporated by reference as if set forth in their entireties.

Example of the pH adjusting agent includes but is not limited to (a) nitric acid, sulfuric acid, tartaric acid, succinic acid, citric acid, malic acid, malonic acid, various fatty acids, various polycarboxylic acids and combinations thereof to lower pH of the polishing formulation; and (b) potassium hydroxide, sodium hydroxide, ammonia hydroxide, cesium hydroxide, quaternary organic ammonium hydroxide (e.g. tetramethylammonium hydroxide), ethylenediamine, piperazine, polyethyleneimine, modified polyethyleneimine, and combinations thereof to raise pH of the polishing formulation; and in an amount ranging from about 0 wt. % to 3 wt. %; preferably 0.001 wt. % to 1 wt. %; more preferably 0.01 wt. % to 0.5 wt. % pH adjusting agent.

The polishing formulation has a pH from 2 to 12, 3 to 10, 4 to 9, or 6 to 8.

Dispersing agents can be used to improve colloidal stability of particles. Dispersing agents may comprise surfactants and polymers. Examples of dispersing agents include poly-acrylic acid, poly-meth acrylic acid.

The rest of the formulation is liquid carrier which provides the principle portion of the liquid component.

The liquid carrier includes but is not limited to DI water, a polar solvent and a mixture of DI water and polar solvent. The polar solvent can be any alcohol, ether, ketone, or other polar reagent. Examples of polar solvents include alcohols, such as isopropyl alcohol, ethers, such as tetrahydrofuran and diethyl ether, and ketones, such as acetone. Advantageously the water is deionized (DI) water.

The formulations can be made in concentrated forms and diluted with DI water at the time of polishing in order to reduce costs associated with shipping and handling. The dilutions can range from 1 part slurry concentrate: 0 parts water to 1 part slurry concentrate: 1000 parts water, or between 1 part slurry concentrate: 3 parts water to 1 part slurry concentrate: 100 parts water, or between 1 part slurry concentrate: 5 parts water to 1 part slurry concentrate: 50 parts water.

Formulations of this invention are used to polish patterned wafer with copper interconnect lines to provide high removal rate of copper and yet low dishing.

Copper CMP is generally carried out in three steps. In the first step, bulk copper is removed with polishing conditions with high removal rates from the patterned wafer and a planarized surface is formed. In the second step, a more controlled polishing is performed to remove remaining copper to reduce dishing and then stopping at the barrier layer. The third step involves removal of barrier layer. Formulations of this invention can be used in steps 1 and 2 as described above. In the step 1, higher downforce or table speed can be used to polish copper at high removal rates and a lower downforce or lower table speed for step 2 of the copper CMP. Typically, the first step polish is carried out at down-force of 2.5 psi or higher. The second step polish is carried out down-force of 1.5 psi or lower. It is desired that the copper removal rates be high to obtain acceptable throughput for a wafer production. Preferably the desired CMP removal rate for the second step CMP is at least 3000 Amin or more preferably or more preferably more than 4000 Å/min. For the first step, the desired removal rate is more than 6000 Å/min.

Formulations of this invention are able to polish copper at high selectivity to the barrier or polish stop layer. Preferred removal rate selectivity between copper and the barrier layer is more than 50. These formulation may be used in variety of integration schemes using copper or copper based alloys as interconnect material with a range of possible barrier/polish stop layers including but not limited to Ta, TaN, Ti, TiN, Co, Ru.

The present invention is further demonstrated by the examples below.

### General Experimental Procedure

The associated methods described herein entail use of the aforementioned slurry for chemical mechanical planarization of substrates comprised of copper.

In the methods, a substrate (e.g., a wafer with copper surface) is placed face-down on a polishing pad which is fixedly attached to a rotatable platen of a CMP polisher. In this manner, the substrate to be polished and planarized is placed in direct contact with the polishing pad. A wafer carrier system or polishing head is used to hold the substrate in place and to apply a downward pressure against the backside of the substrate during CMP processing while the platen and the substrate are rotated. The polishing formulation is applied (usually continuously) on the pad during CMP processing to effect the removal of material to planarize the substrate.

The polishing slurry and associated methods described herein are effective for CMP of a wide variety of substrates, including most of substrates having, particularly useful for polishing copper substrates.

In the examples presented below, CMP experiments were run using the procedures and experimental conditions given below.

The CMP tool that was used in the examples is a Reflexion® LK, manufactured by Applied Materials, 3050 Boweres Avenue, Santa Clara, Calif., 95054.

Polishing was carried out with table-speed of 93 RPM with 300 mL/min. slurry flow rare on VP9280® pad from Dow Chemicals. For removal rate data, electroplated copper wafers were used for polishing. Dishing data was obtained on MIT754 patterned wafers with Cu lines in TEOS dielectric with Ta/TaN barrier layer. Patterned wafer polishing involved polishing at 2.5 psi downforce for about 75 seconds for the first step of polish, followed by polishing at 1.5 psi till the defined end-point for polishing. Defined end-point was when all copper overburden is cleared from the patterned wafer surface as detected by optical end-point technique on Reflexion® LK. Dishing measurement were performed using profilometric technique.

Abrasive particles were colloidal silica particles having Mean Particle Size-MPS ranges about 15 nm to 160 nm were supplied by the following companies: Nalco Water, An Ecolab Company at 1601 W Diehl Rd, Naperville, Ill. 60563, USA; Fuso Chemical CO., Ltd. at Ogura Bldg. 6-6, Nihonbashi-kobuna-cho, Chuo-ku, Tokyo 103-00 Japan; and JGC Catalysts and Chemicals Ltd. at 16th Floor, Solid Square East Tower, 580 Horikawa-cho, Saiwai-ku, Kawasaki City, Kanagawa 212-0013 Japan.

### WORKING EXAMPLE

### Example 1

CMP polishing formulations as shown in Table 1 all comprised 416 ppm 1,2,4-Triazole as corrosion inhibitor, 833 ppm colloidal silica (Mean Particle Size-MPS ranges about 15 nm to 160 nm; about 40 ppm ethylene diamine, (2-Hydroxyethyl)trimethylammonium bicarbonate, or the combinations of ethylene diamine and (2-Hydroxyethyl)trimethylammonium bicarbonate), 1 wt. % hydrogen peroxide, 5.5 wt. % glycine, 9.5 wt. % alanine, and water.

pH for all formulations in all examples is between 7.20 to 7.30.

TABLE 1

| Formulation# | Abrasives |
|---|---|
| 1 | Nalco, ~15 nm MPS, |
| | spherical |
| 2 | Fuso, ~15 nm MPS, spherical |
| 3 | Nalco, ~27 nm MPS, |
| | spherical |
| 4 | Fuso, ~27 nm MPS, spherical |
| 5 | Nalco, ~50 nm MPS, |
| | spherical |
| 6 | Fuso, ~50 nm MPS, cocoon |
| 7 | Fuso, ~125 nm MPS, cocoon |
| 8 | Fuso, ~140 nm MPS, |
| | aggregates |
| 9 | JGC C&C, ~160 nm MPS, |
| | spherical |

Dishing performance of the formulations were observed for large and high pattern density copper lines featuring 100/100 μm and 9/1 μm. The results were listed in Table 2.

As shown in Table 2, it is clear that while providing high removal rates, the dishing performance is much better for abrasives particles having relative smaller MPS than the abrasives particles having relative larger sizes.

TABLE 2

| | Cu removal | | |
|---|---|---|---|
| | rates at 2.5/1.5 | Dishing of | Dishing of |
| Formulation | psi down forces | 100/100 μm Cu | 9/1 μm Cu lines |
| # | (Å/min) | lines (Å) | (Å) |
| 1 | 6,204/4,084 | 779 | 442 |
| 2 | 5,492/3,451 | 773 | 428 |
| 3 | 5,140/3,712 | 968 | 620 |
| 4 | 5,629/3,519 | 873 | 486 |
| 5 | 4,414/3,109 | 1,037 | 658 |
| 6 | 8,453/5,695 | 924 | 560 |
| 7 | 7,618/4,874 | 999 | 843 |
| 8 | 8,493/4,824 | 1,130 | 868 |
| 9 | 7,757/4,574 | 1156 | 797 |

Ammonium dodecyl sulfate (ADS) (80 to 250 ppm) was added to CMP polishing formulations having relative smaller abrasives MPS, the dishing performance was further improved.

### Example 2

CMP polishing formulations as shown in Table 3 all comprised 416 ppm 1,2,4-Triazole as corrosion inhibitor, 833 ppm colloidal silica (from Fuso Chemical CO) having MPS about 15nm; about 40 ppm ethylene diamine, (2-Hydroxyethyl)trimethylammonium bicarbonate, or the combinations of ethylene diamine and (2-Hydroxyethyl)trimethylammonium bicarbonate, 1 wt. % hydrogen peroxide, 5.5 wt. % glycine, 9.5 wt. %alanine, and water.

pH for all formulations in all examples is between 7.20 to 7.30.

Formulation 11 used colloidal silica particles (Fuso BS-1L) having spherical shapes with no surface modification.

Formulation 12 (Fuso BS-1L-C) used colloidal silica particles having spherical shapes with surface modified by cation amine groups

Formulation 13 (Fuso BS-1L-D) and 14 (Fuso PL-1L-D) used colloidal silica particles having spherical shapes with surface modified by anion sulfonic acid group(s).

Cu removal rates at 2.5 and 1.5 psi down forces and dishing performance of the formulations were observed for large and high pattern density copper lines featuring 100/100 μm and 9/1 μm. The results were listed in Table 3.

TABLE 3

| | Cu removal | | |
|---|---|---|---|
| | rates at 2.5/1.5 | Dishing of | Dishing of |
| Formulation | psi down forces | 100/100 μm Cu | 9/1 μm Cu lines |
| # | (Å/min) | lines (Å) | (Å) |
| 11 | 5,492/3,451 | 773 | 428 |
| 12 | 5,786/3,730 | 776 | 445 |
| 13 | 4,718/3,181 | 779 | 438 |
| 14 | 5,671/3,605 | 768 | 403 |

As shown in Table 3, it is clear that all tested formulations with non-surface-modified, cation and anion surface-modified abrasives having small MPS rendered very similar level of dishing reduction on large and/or high pattern density copper features/lines.

Formulations comprising about 4 nm to about 30 nm MPS abrasive particles provide removal rates comparable with formulations comprising 30 nm to 200 nm MPS abrasive particles and yet provide significant reduction in Cu line dishing.

The embodiments of this invention listed above, including the working example, are exemplary of numerous embodiments that may be made of this invention. It is contemplated that numerous other configurations of the process may be used, and the materials used in the process may be elected from numerous materials other than those specifically disclosed.

1. A copper chemical mechanical planarization (CMP) polishing formulation comprising:
abrasive particles selected from the group consisting of fumed silica, colloidal silica, high purity colloidal silica, fumed alumina, colloidal alumina, cerium oxide, titanium dioxide, zirconium oxide, surface modified or lattice doped inorganic oxide particles, polystyrene, polymethyl methacrylate, mica, hydrated aluminum silicate, and combinations thereof;
at least two amino acids;
oxidizer;
corrosion inhibitor;
and
liquid carrier;
wherein
the formulation has a pH from 2 to 12;
wherein the at least two amino acids are each independently selected from the group consisting of aminoacetic acid (glycine), serine, lysine, glutamine, L-alanine, DL-alanine, Beta-alanine, iminoacetic acid, asparagine, aspartic acid, valine, sarcosine, bicine, tricin, proline, and combinations thereof; and weight concentration ratio of one amino acid to another amino acid used in the slurry ranges from 20:80 to 80:20; and
the abrasive particles have mean particle size of ≤40 nm or ≤30 nm.

2. The chemical mechanical planarization (CMP) polishing formulation of claim 1, wherein the abrasive particles range from 0.005 to 0.5 wt. %, or 0.01 to 0.25 wt. % and the abrasive particles have mean particle size of 4 nm to 30 nm, or 5 to 20 nm; and each amino acid of the at least two amino acid ranges from 0.01 wt. % to 20.0 wt. %.

3. (canceled)

4. (canceled)

5. (canceled)

6. (canceled)

7. The chemical mechanical planarization (CMP) polishing formulation of claim 1, wherein the oxidizer is selected from the group consisting of hydrogen peroxide, ammonium dichromate, ammonium perchlorate, ammonium persulfate, benzoyl peroxide, bromates, calcium hypochlorite, ceric sulfate, chlorates, chromium trioxide, ferric trioxide, ferric chloride, iodates, iodine, magnesium perchlorate, magnesium dioxide, nitrates, periodic acid, permanganic acid, potassium dichromate, potassium ferricyanide, potassium permanganate, potassium persulfate, sodium bismuthate, sodium chlorite, sodium dichromate, sodium nitrite, sodium perborate, sulfates, peracetic acid, urea-hydrogen peroxide, perchloric acid, di-t-butyl peroxide, monopersulfates, dipersulfates, and combinations thereof; and the oxidizer ranges from 0.1 wt. % to 20 wt. %, or 0.25 wt. % to 5 wt. %; and
the corrosion inhibitor is selected from the group consisting of nitrogenous cyclic compound selected from the group consisting of 1, 2, 3-triazole, 1, 2, 4 triazole, 3-amino-1,2,4-triazole, 1, 2, 3-benzotriazole, 5-methylbenzotriazole, benzotriazole, 1-hydroxybenzotriazole, 4-hydroxybenzotriazole, 4-amino-4H-1, 2, 4-triazole, benzimidazole; 5-amino triazole, benzothiazole, triazinethiol, triazinedithiol, and triazinetrithiol; isocyanurate and combinations thereof; and ranges from 0.1 ppm to 20,000 ppm by weight, or 20 ppm to 10,000 ppm by weight.

8. (canceled)

9. (canceled)

10. The chemical mechanical planarization (CMP) polishing formulation of claim 1, further comprises at least one selected from the group consisting of
5 to 1000ppm, or 10 to 500 ppm of planarization efficiency enhancer selected from the group consisting of choline salt selected from the group consisting of 2-hydroxyethyl)trimethylammonium bicarbonate, choline hydroxide, choline p-toluene-sulfonate, choline bitartrate, and combinations thereof; an organic amine selected from the group consisting of ethylene diamine, propylene diamine, and combinations thereof; and combinations thereof; and
0.0005 to 0.5 wt. %, or 0.001 to 0.3 wt. % of a surfactant containing one selected from the group consisting of phenyl ethoxylate, acetylenic diol, sulfate, sulfonate, glyceroal propoxylate, glyceroal ethoxylate, polysorbate surfactant, non-ionic alkyl ethoxylate, glycerol propoxylate-block-ethoxylate, amine oxide, glycolic acid ethoxylate oleyl ether, polyethylene glycol, polyethylene oxide, ethoxylated alcohols, ethoxylate-propoxylate, polyether defoaming dispersion, and combinations thereof.

11. (canceled)

12. (canceled)

13. (canceled)

14. The chemical mechanical planarization (CMP) polishing formulation of claim 1, further comprises at least one selected from the group consisting of pH adjusting agent, biocide, dispersing agent, and wetting agent.

15. The chemical mechanical planarization (CMP) polishing formulation of claim 1, wherein the CMP polishing formulation comprises 0.001 to 0.5 wt. %, or 0.01 to 0.25 wt. % of colloidal silica having a MPS ≤30 nm or ≤20 nm; at least two amino acids and each is selected from the group consisting of aminoacetic acid (glycine), alanine, bicine, and sarcosine; hydrogen peroxide; 1,2,4-triazole or 5-amino triazole; water; and the pH is from 4 to 9 or 6 to 8.

16. The chemical mechanical planarization (CMP) polishing formulation of claim 1, wherein the CMP polishing formulation comprises 0.005 to 0.5 wt. %, or 0.01 to 0.25 wt. % of colloidal silica having a MPS ≤30 nm or ≤20 nm; at least two amino acids and each is selected from the group consisting of aminoacetic acid (glycine), alanine, bicine, and sarcosine; hydrogen peroxide; 1,2,4-triazole or 5-amino triazole; 10 to 500 ppm, or 10 to 100 ppm of ethylene diamine, (2-Hydroxyethyl)trimethylammonium bicarbonate, or combinations thereof; water; and the pH is from 4 to 9 or 6 to 8.

17. The chemical mechanical planarization (CMP) polishing formulation of claim 1, wherein the CMP polishing formulation comprises of 0.001 to 0.5 wt. % or 0.01 to 0.25 wt. % of colloidal silica having a MPS ≤20 nm; at least two amino acids and each is selected from the group consisting of aminoacetic acid (glycine), alanine, bicine, and sarcosine; hydrogen peroxide; 1,2,4-triazole or 5-amino triazole; 10 to 500 ppm, or 10 to 100 ppm of ethylene diamine, (2-Hydroxyethyl)trimethylammonium bicarbonate, or combinations thereof; 0.0005 to 0.5 wt. %, or 0.001 to 0.3 wt. % of a surfactant containing one selected from the group consisting of phenyl ethoxylate, acetylenic diol, ethoxylate-propoxylate, polyether, sulfate or sulfonate selected from the group consisting of ammonium dodecyl sulfate, sodium decyl sulfate, tetradecyl sulfate sodium salt, linear alkylbenzene sulfate, and combinations thereof; water; and the pH is from 4 to 9 or 6 to 8.

18. A method of chemical mechanical planarization polishing a copper containing semiconductor substrate, comprising steps of:
providing the semiconductor substrate having a surface containing copper;
providing a polishing pad;
providing the chemical mechanical planarization (CMP) polishing formulation comprising:
abrasive particles selected from the group consisting of fumed silica, colloidal silica, high purity colloidal silica, fumed alumina, colloidal alumina, cerium oxide, titanium dioxide, zirconium oxide, surface modified or lattice doped inorganic oxide particles, polystyrene, polymethyl methacrylate, mica, hydrated aluminum silicate, and combinations thereof;
at least two amino acids,
oxidizer,
corrosion inhibitor,
and
liquid carrier,
wherein
the formulation has a pH from 2 to 12;
the at least two amino acids are each independently selected from the group consisting of aminoacetic acid (glycine), serine, lysine, glutamine, L-alanine, DL-alanine, Beta-alanine, iminoacetic acid, asparagine, aspartic acid, valine, sarcosine, bicine, tricin, proline, and combinations thereof; and weight concentration ratio of one amino acid to another amino acid used in the slurry ranges from 20:80 to 80:20; and
the abrasive particles have mean particle size of ≤40 nm or ≤30 nm;
contacting the surface of the semiconductor substrate with the polishing pad and the chemical mechanical planarization (CMP) polishing formulation; and
polishing the surface of the semiconductor;
wherein at least a portion of the surface containing copper is in contact with both the polishing pad and the chemical mechanical planarization (CMP) polishing formulation.

19. A system of chemical mechanical planarization polishing, comprising
a semiconductor substrate having a surface containing copper;
providing a polishing pad;
providing the chemical mechanical planarization (CMP) polishing formulation comprising:
abrasive particles selected from the group consisting of fumed silica, colloidal silica, high purity colloidal silica, fumed alumina, colloidal alumina, cerium oxide, titanium dioxide, zirconium oxide, surface modified or lattice doped inorganic oxide particles, polystyrene, polymethyl methacrylate, mica, hydrated aluminum silicate, and combinations thereof;
at least two amino acids,
oxidizer,
corrosion inhibitor,
and
liquid carrier,
wherein
the formulation has a pH from 2 to 12; and
the at least two amino acids are each independently selected from the group consisting of aminoacetic acid (glycine), serine, lysine, glutamine, L-alanine, DL-alanine, Beta-alanine, iminoacetic acid, asparagine, aspartic acid, valine, sarcosine, bicine, tricin, proline, and combinations thereof; and weight concentration ratio of one amino acid to another amino acid used in the slurry ranges from 20:80 to 80:20; and
the abrasive particles have mean particle size of ≤40 nm or ≤30 nm;
wherein at least a portion of the surface containing copper is in contact with both the polishing pad and the chemical mechanical planarization (CMP) polishing formulation.

20. The method of chemical mechanical planarization polishing a copper containing semiconductor substrate of claim 18; wherein
the abrasive particles range from 0.005 to 0.5 wt. % or 0.01 to 0.25 wt. % and the abrasive particles have mean particle size of 4 nm to 30 nm or 5 to 20 nm;
each amino acid of the at least two amino acid ranges from 0.01 wt. % to 20.0 wt. %;
the oxidizer is selected from the group consisting of hydrogen peroxide, ammonium dichromate, ammonium perchlorate, ammonium persulfate, benzoyl peroxide, bromates, calcium hypochlorite, ceric sulfate, chlorates, chromium trioxide, ferric trioxide, ferric chloride, iodates, iodine, magnesium perchlorate, magnesium dioxide, nitrates, periodic acid, permanganic acid, potassium dichromate, potassium ferricyanide, potassium permanganate, potassium persulfate, sodium bismuthate, sodium chlorite, sodium dichromate, sodium nitrite, sodium perborate, sulfates, peracetic acid, urea-hydrogen peroxide, perchloric acid, di-t-butyl peroxide, monopersulfates, dipersulfates, and combinations thereof; and the oxidizer ranges from 0.1 wt. % to 20 wt. % or 0.25 wt. % to 5 wt. %; and
the corrosion inhibitor is selected from the group consisting of nitrogenous cyclic compound selected from the group consisting of 1, 2, 3-triazole, 1, 2, 4 triazole, 3-amino-1,2,4-triazole, 1, 2, 3-benzotriazole, 5-methylbenzotriazole, benzotriazole, 1-hydroxybenzotriazole, 4-hydroxybenzotriazole, 4-amino-4H-1, 2, 4-triazole, benzimidazole; 5-amino triazole, benzothiazole, triazinethiol, triazinedithiol, and triazinetrithiol; isocyanurate and combinations thereof; and the corrosion inhibitor ranges from 0.1 ppm to 20,000 ppm by weight, or 20 ppm to 10,000 ppm by weight.

21. The method of chemical mechanical planarization polishing a copper containing semiconductor substrate of claim 18; wherein the chemical mechanical planarization (CMP) polishing formulation further comprises at least one selected from the group consisting of
5 to 1000 ppm or 10 to 500 ppm of planarization efficiency enhancer selected from the group consisting of choline salt selected from the group consisting of 2-hydroxyethyl)trimethylammonium bicarbonate, choline hydroxide, choline p-toluene-sulfonate, choline bitartrate, and combinations thereof; an organic amine selected from the group consisting of ethylene diamine, propylene diamine, and combinations thereof;
and combinations thereof;
0.0005 to 0.5 wt. % or 0.001 to 0.3 wt. % of a surfactant containing one selected from the group consisting of phenyl ethoxylate, acetylenic diol, sulfate, sulfonate, glyceroal propoxylate, glyceroal ethoxylate, polysorbate surfactant, non-ionic alkyl ethoxylate, glycerol propoxylate-block-ethoxylate, amine oxide, glycolic acid ethoxylate oleyl ether, polyethylene glycol, polyethylene oxide, ethoxylated alcohols, ethoxylate-propoxylate, polyether defoaming dispersion, and combinations thereof;
pH adjusting agent;
biocide;
dispersing agent; and
wetting agent.

22. The method of chemical mechanical planarization polishing a copper containing semiconductor substrate of claim 18; wherein the CMP polishing formulation comprises 0.001 to 0.5 wt. % or 0.01 to 0.25 wt. % of colloidal silica having a MPS 30 nm or 20 nm; at least two amino acids and each is selected from the group consisting of aminoacetic acid (glycine), alanine, bicine, and sarcosine; hydrogen peroxide; 1,2,4-triazole or 5-amino triazole; water; and the pH is from 4 to 9 or 6 to 8.

23. The method of chemical mechanical planarization polishing a copper containing semiconductor substrate of claim 18; wherein the CMP polishing formulation comprises 0.005 to 0.5 wt. % or 0.01 to 0.25 wt. % of colloidal silica having a MPS 30 nm or 20 nm;
at least two amino acids and each is selected from the group consisting of aminoacetic acid (glycine), alanine, bicine, and sarcosine; hydrogen peroxide; 1,2,4-triazole or 5-amino triazole; 10 to 500 ppm or 10 to 100 ppm of ethylene diamine, (2-Hydroxyethyl)trimethylammonium bicarbonate, or combinations thereof; water; and the pH is from 4 to 9 or 6 to 8 .

24. The method of chemical mechanical planarization polishing a copper containing semiconductor substrate of claim 18; wherein the CMP polishing formulation comprises of 0.001 to 0.5 wt. % or 0.01 to 0.25 wt. % of colloidal silica having a MPS≤20nm; at least two amino acids and each is selected from the group consisting of aminoacetic acid (glycine), alanine, bicine, and sarcosine; hydrogen peroxide; 1,2,4-triazole or 5-amino triazole; 10 to 500 ppm or 10 to 100 ppm of ethylene diamine, (2-Hydroxyethyl)trimethylammonium bicarbonate, or combinations thereof; 0.0005 to 0.5 wt. % or 0.001 to 0.3 wt. % of a surfactant containing one selected from the group consisting of phenyl ethoxylate, acetylenic diol, ethoxylate-propoxylate, polyether, sulfate or sulfonate selected from the group consisting of ammonium dodecyl sulfate, sodium decyl sulfate, tetradecyl sulfate sodium salt, linear alkylbenzene sulfate, and combinations thereof; water; and the pH is from 4 to 9 or 6 to 8.

25. The system of chemical mechanical planarization polishing of claim 19; wherein the abrasive particles range from 0.005 to 0.5 wt. % or 0.01 to 0.25 wt. % and the abrasive particles have mean particle size of 4 nm to 30 nm or 5 to 20 nm;
each amino acid of the at least two amino acid ranges from 0.01 wt. % to 20.0 wt. %;
the oxidizer is selected from the group consisting of hydrogen peroxide, ammonium dichromate, ammonium perchlorate, ammonium persulfate, benzoyl peroxide, bromates, calcium hypochlorite, ceric sulfate, chlorates, chromium trioxide, ferric trioxide, ferric chloride, iodates, iodine, magnesium perchlorate, magnesium dioxide, nitrates, periodic acid, permanganic acid, potassium dichromate, potassium ferricyanide, potassium permanganate, potassium persulfate, sodium bismuthate, sodium chlorite, sodium dichromate, sodium nitrite, sodium perborate, sulfates, peracetic acid, urea-hydrogen peroxide, perchloric acid, di-t-butyl peroxide, monopersulfates, dipersulfates, and combinations thereof; and the oxidizer ranges from 0.1 wt. % to 20 wt. % or 0.25 wt. % to 5 wt. %; and
the corrosion inhibitor is selected from the group consisting of nitrogenous cyclic compound selected from the group consisting of 1, 2, 3-triazole, 1, 2, 4 triazole, 3-amino-1,2,4-triazole, 1, 2, 3-benzotriazole, 5-methylbenzotriazole, benzotriazole, 1-hydroxybenzotriazole, 4-hydroxybenzotriazole, 4-amino-4H-1, 2, 4-triazole, benzimidazole; 5-amino triazole, benzothiazole, triazinethiol, triazinedithiol, and triazinetrithiol; isocyanurate and combinations thereof; and the corrosion inhibitor ranges from 0.1 ppm to 20,000 ppm by weight, or 20 ppm to 10,000 ppm by weight.

26. The system of chemical mechanical planarization polishing of claim 19; wherein the chemical mechanical planarization (CMP) polishing formulation further comprises at least one selected from the group consisting of
5 to 1000ppm or 10 to 500 ppm of planarization efficiency enhancer selected from the group consisting of choline salt selected from the group consisting of 2-hydroxyethyl)trimethylammonium bicarbonate, choline hydroxide, choline p-toluene-sulfonate, choline bitartrate, and combinations thereof; an organic amine selected from the group consisting of ethylene diamine, propylene diamine, and combinations thereof; and combinations thereof;
0.0005 to 0.5 wt. % or 0.001 to 0.3 wt. % of a surfactant containing one selected from the group consisting of phenyl ethoxylate, acetylenic diol, sulfate, sulfonate, glyceroal propoxylate, glyceroal ethoxylate, polysorbate surfactant, non-ionic alkyl ethoxylate, glycerol propoxylate-block-ethoxylate, amine oxide, glycolic acid ethoxylate oleyl ether, polyethylene glycol, polyethylene oxide, ethoxylated alcohols, ethoxylate-propoxylate, polyether defoaming dispersion, and combinations thereof;
pH adjusting agent,
biocide,
dispersing agent, and
wetting agent. 27, (New) The system of chemical mechanical planarization polishing of claim 19;
wherein the CMP polishing formulation comprises 0.001 to 0.5 wt. % or 0.01 to 0.25 wt. % of colloidal silica having a MPS 30nm or 20nm; at least two amino acids and each is selected from the group consisting of aminoacetic acid (glycine), alanine, bicine, and sarcosine; hydrogen peroxide; 1,2,4-triazole or 5-amino triazole; water; and the pH is from 4 to 9 or 6 to 8.

28. The system of chemical mechanical planarization polishing of claim 19;
wherein the CMP polishing formulation comprises 0.005 to 0.5 wt. % or 0.01 to 0.25 wt. % of colloidal silica having a MPS 30nm or 20nm; at least two amino acids and each is selected from the group consisting of aminoacetic acid (glycine), alanine, bicine, and sarcosine; hydrogen peroxide; 1,2,4-triazole or 5-amino triazole; 10 to 500 ppm or 10 to 100 ppm of ethylene diamine, (2-Hydroxyethyl)trimethylammonium bicarbonate, or combinations thereof; water; and the pH is from 4 to 9 or 6 to 8 .

29. The system of chemical mechanical planarization polishing of claim 19; wherein the CMP polishing formulation comprises of 0.001 to 0.5 wt. % or 0.01 to 0.25 wt. % of colloidal silica having a MPS 20 nm; at least two amino acids and each is selected from the group consisting of aminoacetic acid (glycine), alanine, bicine, and sarcosine; hydrogen peroxide; 1,2,4-triazole or 5-amino triazole; 10 to 500 ppm or 10 to 100 ppm of ethylene diamine, (2-Hydroxyethyl)trimethylammonium bicarbonate, or combinations thereof; 0.0005 to 0.5 wt. % or 0.001 to 0.3 wt. % of a surfactant containing one selected from the group consisting of phenyl ethoxylate, acetylenic diol, ethoxylate-propoxylate, polyether, sulfate or sulfonate selected from the group consisting of ammonium dodecyl sulfate, sodium decyl sulfate, tetradecyl sulfate sodium salt, linear alkylbenzene sulfate, and combinations thereof; water; and the pH is from 4 to 9 or 6 to 8.
